(19) United States
(12) Patent Application Publication
(10) Pub. No.: US 2017/0369986 A1
(43) Pub. Date: Dec. 28, 2017

(54) METHOD FOR PREPARING COPPER THIN FILM BY USING SINGLE CRYSTAL COPPER TARGET

(71) Applicant: PUSAN NATIONAL UNIVERSITY INDUSTRIAL UNIVERSITY COOPERATION FOUNDATION, Busan (KR)

(72) Inventors: Se-young Jeong, Busan (KR); Ji-young Kim, Yangsan-si (KR); Seung-hun Lee, Ulsan (KR); Tae-woo Lee, Daejeon (KR); Sang-eon Park, Busan (KR); Chae-ryong Cho, Busan (KR)

(73) Assignee: PUSAN NATIONAL UNIVERSITY INDUSTRIAL UNIVERSITY COOPERATION FOUNDATION

(21) Appl. No.: 15/696,393

(22) Filed: Sep. 6, 2017

Related U.S. Application Data
(63) Continuation of application No. PCT/KR2015/002837, filed on Mar. 23, 2015.

(51) Int. Cl. C23C 14/34; C23C 14/18; C30B 23/02; C30B 29/02; C30B 23/08; C30B 15/00

(52) U.S. Cl. CPC C23C 14/3414; C30B 29/02; C30B 23/08; C23C 14/185; C30B 23/025; C30B 15/00

(57) ABSTRACT

A method of manufacturing a copper thin film using a single-crystal copper target, and more particularly, a method of manufacturing a copper thin film using a single-crystal copper target, wherein a copper thin film is deposited on a sapphire disk substrate through high-frequency sputtering using a single-crystal copper target grown through a Czochralski process, and may thus exhibit high quality in terms of crystallinity. The method includes depositing a copper thin film on a sapphire disk substrate through a high-frequency sputtering process using a disk-shaped single-crystal copper target obtained by cutting cylindrical single-crystal copper grown through a Czochralski process.

### REFERENCE TO RELATED APPLICATIONS

This is a continuation of International Patent Application PCT/KR2015/002837 filed on Mar. 23, 2015, which designates the United States, the entire contents of which are incorporated herein by reference.

### FIELD OF THE INVENTION

The present invention relates to a method of manufacturing a copper thin film using a single-crystal copper target, and more particularly to a method of manufacturing a copper thin film using a single-crystal copper target, in which a copper thin film is deposited on a sapphire disk substrate through a high-frequency sputtering process using a single-crystal copper target grown through a Czochralski process, whereby the resulting copper thin film may exhibit high quality in terms of crystallinity.

### BACKGROUND OF THE INVENTION

Typically, a high-frequency sputtering deposition process is performed in a manner in which a high frequency is applied to a target material in a vacuum, whereby the target material is ionized and thus atoms and molecules thereof are deposited on the surface of a substrate positioned nearby, thus forming a thin film.

The high-frequency sputtering deposition process is mainly employed in the formation of a copper thin film on the surface of a substrate. Specifically, a substrate and a copper target are placed in a vacuum space, and a high frequency is applied to the copper target, thereby forming a copper thin film on the surface of the substrate.

A conventional copper target, employed when the copper thin film is formed using the high-frequency sputtering deposition process, is a polycrystalline or amorphous copper target. In this case, the copper thin film formed on the surface of the substrate has poor quality and is easily stripped from the substrate, which is undesirable. Despite the high demand for copper thin film, limitations are imposed on the easy use of such a copper target.

### SUMMARY OF THE INVENTION

Accordingly, the present invention has been made keeping in mind the problems encountered in the related art, and an objective of the present invention is to provide a method of manufacturing a copper thin film using a single-crystal copper target, in which, in order to prevent the quality of a copper thin film from decreasing due to the use of a conventional copper target upon forming a copper thin film on the surface of a substrate through a high-frequency sputtering deposition process, a single-crystal copper target grown through a Czochralski process may be used to thus deposit a high-quality copper thin film on the surface of a sapphire disk substrate.

The objective of the present disclosure is not limited to the foregoing, and other objectives not disclosed herein will be able to be readily understood through the following description.

Therefore, the present invention provides a method of manufacturing a copper thin film using a single-crystal copper target, comprising depositing a copper thin film on a sapphire disk substrate through a high-frequency sputtering process using a disk-shaped single-crystal copper target obtained by cutting cylindrical single-crystal copper grown through a Czochralski process.

The height of a peak (111) of the copper thin film is at least one times the height of a peak (0001) of the sapphire disk substrate on an X-ray diffraction (XRD) pattern.

The copper thin film is characterized in that a resistivity drop, in which resistivity is lower than an average resistivity, occurs in the range from room temperature to 200° C.

The high-frequency sputtering may be performed by applying a high-frequency power of 30 to 60 W at 100 to 200° C. for 2 to 3 hr.

According to the present invention, a high-quality copper thin film can be deposited on the surface of a sapphire disk substrate through a simple high-frequency sputtering process using a disk-shaped single-crystal copper target grown through a Czochralski process, thereby meeting the strong demand for copper thin film and further widening the field of application of the copper thin film.

### BRIEF DESCRIPTION OF THE DRAWINGS

FIG. 1 shows XRD data for the comparison of a copper thin film manufactured according to a preferred embodiment of the present invention and a copper thin film manufactured by a conventional process;

FIG. 2 shows AFM data for the comparison of the copper thin film manufactured according to a preferred embodiment of the present invention and the copper thin film manufactured by a conventional process;

FIG. 3 shows TEM images for the comparison of the copper thin film manufactured according to a preferred embodiment of the present invention and the copper thin film manufactured by a conventional process;

FIG. 4 shows EBSD images for the comparison of the copper thin film manufactured according to a preferred embodiment of the present invention and the copper thin film manufactured by a conventional process; and

FIG. 5 shows Hall data for the comparison of the copper thin film manufactured according to a preferred embodiment of the present invention and the copper thin film manufactured by a conventional process.

### DETAILED DESCRIPTION OF THE INVENTION

The present invention addresses a method of manufacturing a copper thin film using a single-crystal copper target, suitable for forming a copper thin film for use in a solar cell or the like on the surface of a substrate.

In particular, the method of manufacturing a copper thin film using a single-crystal copper target according to the present invention enables the formation of a high-quality copper thin film through a relatively simple process compared to conventional methods, in order to meet the high demand for the copper thin film.

Here, the copper target is a disk-shaped single-crystal copper target obtained by cutting cylindrical single-crystal copper grown through a Czochralski process, the substrate is a sapphire disk-shaped substrate, and the deposition process is a high-frequency sputtering process.

A disk-shaped single-crystal copper ingot, grown through a Czochralski process for preparing a single-crystal ingot, is deposited on the surface of a sapphire disk substrate by way of a high-frequency sputtering process, thus yielding a high-quality copper thin film.

The height of a peak (111) of the copper thin film is at least one times the height of a peak (0001) of the sapphire disk substrate on an XRD pattern. Also, the copper thin film is characterized in that a resistivity drop, in which resistivity drastically decreases compared to an average resistivity, occurs in the range of room temperature to 200° C.

Here, the high-frequency sputtering deposition process is performed by applying a high-frequency power of 30 to 60 W at 100 to 200° C. for 1 to 3 hr in a vacuum. When the processing conditions fall out of the above conditions, the properties of the copper thin film are not exhibited as desired and the quality of the copper thin film may decrease. Hence, the process is preferably carried out under the processing conditions, which are appropriately selected within the above ranges.

Below is a description of a method of manufacturing a copper thin film using a single-crystal copper target according to a preferred embodiment of the present invention and the properties of a copper thin film manufactured thereby.

Specifically, the method of manufacturing a copper thin film using a single-crystal copper target according to a preferred embodiment of the present invention is described as follows.

1. A cylindrical single-crystal copper ingot is grown through a Czochralski process.

2. The cylindrical single-crystal copper ingot is vertically erected and cut in a horizontal direction to obtain a disk shape, thus forming a disk-shaped single-crystal copper target.

3. The disk-shaped single-crystal copper target is subjected to high-frequency sputtering by applying a high-frequency power of 40 W at 150° C. for 2 hr so as to deposit a copper thin film on the surface of a disk-shaped sapphire substrate, thereby completing the formation of a copper thin film.

Next, the properties of the copper thin film manufactured according to a preferred embodiment of the present invention are described in detail based on various test data results.

1. XRD data.

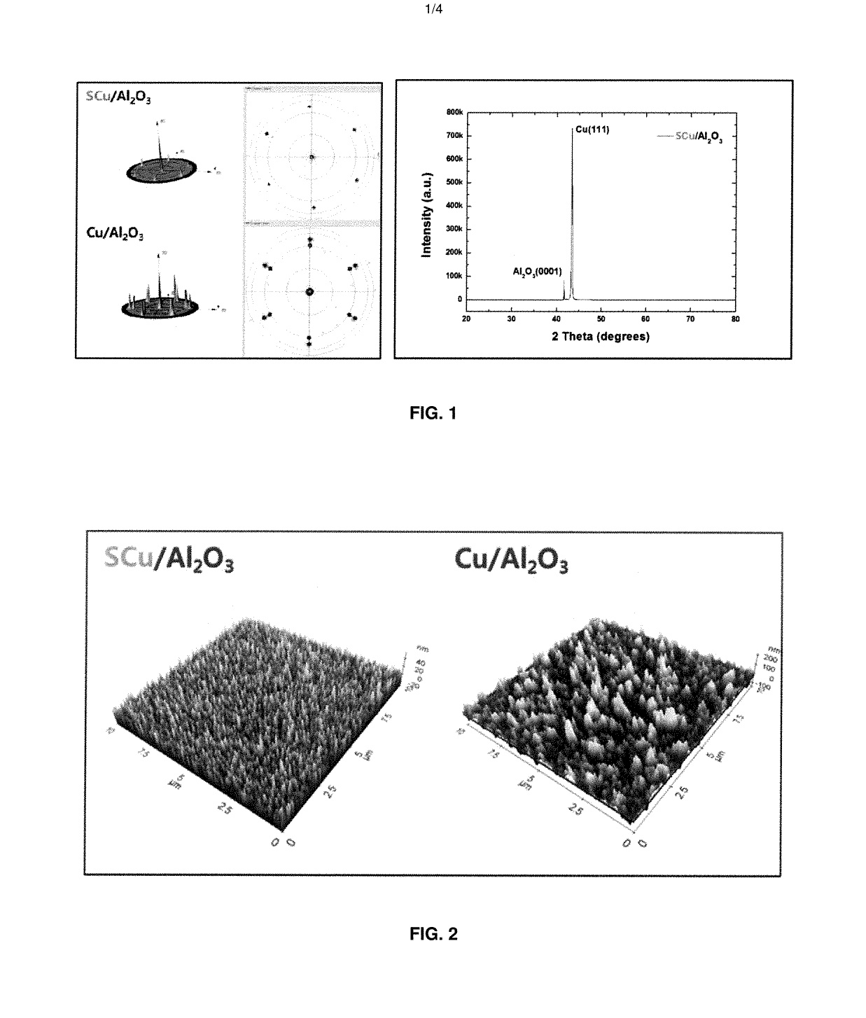

FIG. 1 shows XRD data for the comparison of a copper thin film (SCu/Al₂O₃) manufactured according to a preferred embodiment of the present invention and a copper thin film (Cu/Al₂O₃) manufactured by a conventional process using a typical copper target.

As shown in the left data of FIG. 1, the copper thin film (SCu/Al₂O₃) of the present invention can be confirmed to exhibit superior crystallinity of a Cu (111) plane, compared to the conventional copper thin film (Cu/Al₂O₃) using the typical copper target.

As shown in the right data of FIG. 1, the peak of Cu (111) of the copper thin film (SCu/Al₂O₃) according to the present invention appears to be much higher than the peak of the sapphire substrate (Al₂O₃ (0001)). On the other hand, in the case of the conventional copper thin film (Cu/Al₂O₃), the peak of the thin film is not higher than the peak of the substrate. Specifically, the peak intensity of the copper thin film (SCu/Al₂O₃) is ensured to a level equal to or higher than 106 CPS (counts per second), thereby making it possible to grow a high-quality copper thin film.

2. AFM data

FIG. 2 shows AFM data for the comparison of the copper thin film (SCu/Al₂O₃) manufactured according to a preferred embodiment of the present invention and the copper thin film (Cu/Al₂O₃) manufactured by a conventional process using a typical copper target.

As shown in the AFM data of FIG. 2, the morphology of the copper thin film (SCu/Al₂O₃) of the present invention is uniform but the morphology of the conventional copper thin film is non-uniform. The copper thin film (SCu/Al₂O₃) of the present invention has an RMS (9.11 nm) that is lower than the RMS (45.09 nm) of the conventional copper thin film (Cu/Al₂O₃).

3. TEM image

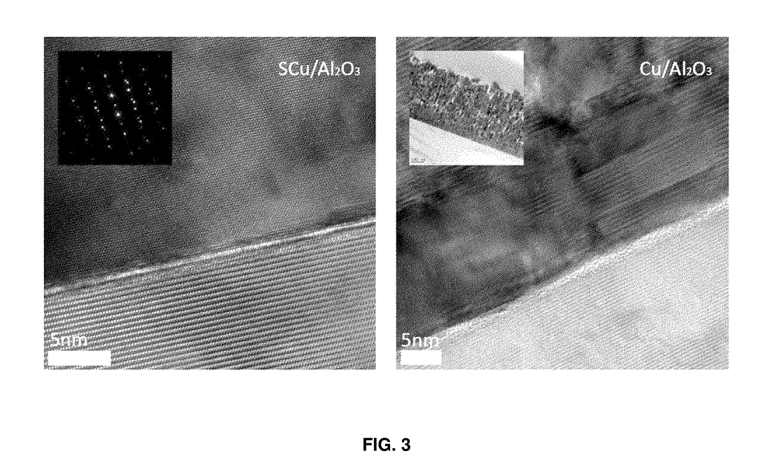

FIG. 3 shows TEM images for the comparison of the copper thin film (SCu/Al₂O₃) manufactured according to a preferred embodiment of the present invention and the copper thin film (Cu/Al₂O₃) manufactured through a conventional process using a typical copper target.

As shown in the TEM images of FIG. 3, the copper thin film (SCu/Al₂O₃) of the present invention is configured such that lattices are uniformly formed like single crystals at the boundary between the substrate and the copper thin film. Also, as seen in the SAED (Selected Area Electron Diffraction) insertion, the copper thin film can be found to be effectively formed on the surface of the substrate.

However, the conventional copper thin film (Cu/Al₂O₃) is configured such that a large number of layer defects and crystal dislocations are formed at the boundary between the thin film and the substrate. As seen in the inserted TEM image, a columnar structure can be confirmed to grow.

4. EBSD image

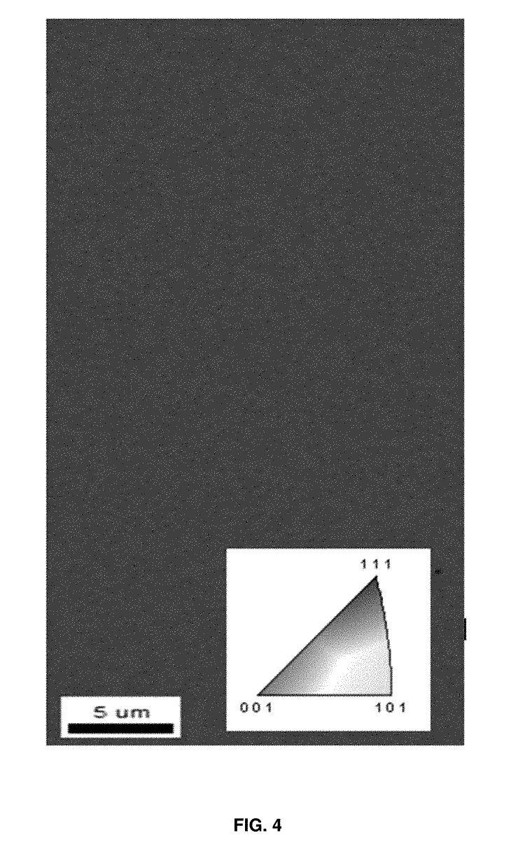

FIG. 4 shows EBSD images for the comparison of the copper thin film (SCu/Al₂O₃) manufactured according to a preferred embodiment of the present invention and the copper thin film (Cu/Al₂O₃) manufactured by a conventional process using a typical copper target.

As shown in the EBSD images of FIG. 4, the copper thin film of the present invention is configured such that no grains are found throughout the entire region of the EBSD image, and is grown in the same (111) direction.

5. Hall data

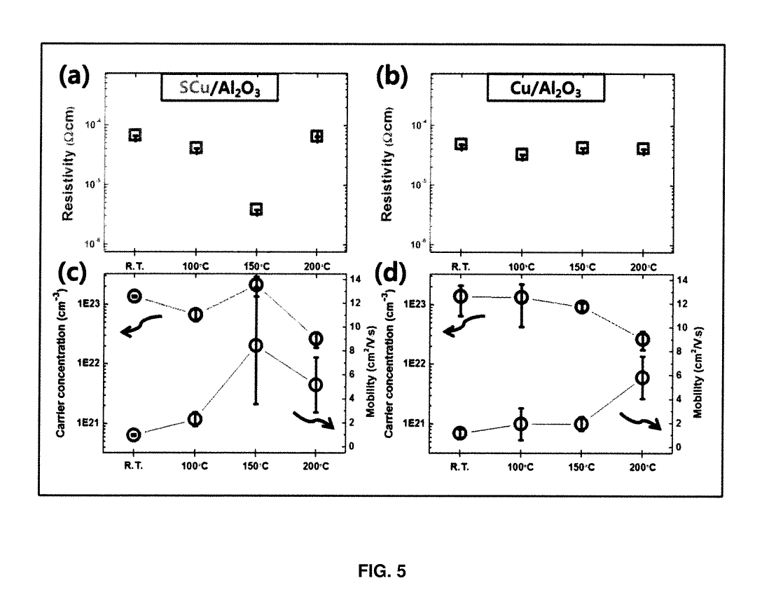

FIG. 5 shows Hall data for the comparison of the copper thin film (SCu/Al₂O₃) manufactured according to a preferred embodiment of the present invention and the copper thin film (Cu/Al₂O₃) manufactured by a conventional process using a typical copper target (using van der Pauw's law).

Based on the Hall data of FIG. 5, in the copper thin film (SCu/Al₂O₃) of the present invention, a resistivity drop, in which resistivity drastically decreases, occurs at about 150° C., as is apparent from (a), but the conventional copper thin film (Cu/Al₂O₃) shows that changes in resistivity fall in the predetermined range, as seen in (b). Also, in the copper thin film (SCu/Al₂O₃) of the present invention, carrier concentration and mobility are remarkably increased at about 150° C., as seen in (c), but the conventional copper thin film (Cu/Al₂O₃) is gradually decreased or increased in carrier concentration and mobility with an increase in temperature, as seen in (d).

The copper thin film (SCu/Al₂O₃) of the present invention has low resistivity properties by virtue of the surface effects thereof and the grain boundary contribution, and is thus highly applicable to ULSI (Ultra-Large Scale Integration) technology.

As described hereinbefore, the method of manufacturing a copper thin film using a single-crystal copper target according to the present invention enables the deposition of a copper thin film on the surface of a sapphire substrate through high-frequency sputtering using a single-crystal copper target, and thus the resulting copper thin film may exhibit high quality while achieving superior crystallinity, uniform morphology, uniform grain distribution and resistivity properties, compared to the conventional copper thin film.

The above embodiment is merely exemplary, and other embodiments variously modified therefrom may be provided by those skilled in the art.

Therefore, the technical scope of the present invention should include not only the above embodiment but variously modified embodiments that fall within the technical spirit of the invention disclosed in the accompanying claims.

The present invention pertains to a method of manufacturing a copper thin film using a single-crystal copper target, and more particularly to a method of manufacturing a copper thin film using a single-crystal copper target, in which a copper thin film is deposited on a sapphire disk substrate through high-frequency sputtering using a single-crystal copper target grown through a Czochralski process, and can thus be applied to the field of the formation of a copper thin film having high quality in terms of crystallinity.

What is claimed is:

1. A method of manufacturing a copper thin film using a single-crystal copper target, comprising depositing a copper thin film on a sapphire disk substrate through a high-frequency sputtering process using a disk-shaped single-crystal copper target obtained by cutting a cylindrical single-crystal copper grown through a Czochralski process.

2. The method of claim 1, wherein a height of a peak (111) of the copper thin film is at least one times a height of a peak (0001) of the sapphire disk substrate on an X-ray diffraction (XRD) pattern.

3. The method of claim 1, wherein, in the copper thin film, a resistivity drop, in which a resistivity is lower than an average resistivity, occurs in a range from room temperature to 200° C.

4. The method of claim 1, wherein the high-frequency sputtering is performed by applying a high-frequency power of 30 to 60 W at 100 to 200° C. for 2 to 3 hr.
